(19) United States
(12) Patent Application Publication
(10) Pub. No.: US 2026/0052952 A1
(43) Pub. Date: Feb. 19, 2026

(54) MASK-TO-DONOR ALIGNMENT FOR LASER-INDUCED FORWARD TRANSFER

(71) Applicant: Coherent LaserSystems GmbH & Co. KG, Göttingen (DE)

(72) Inventors: Muhammad FATAHILAH, Göttingen (DE); Thorge GRIFFEL, Göttingen (DE); André SILL, Braunschweig (DE)

(73) Assignee: Coherent LaserSystems GmbH & Co. KG, Göttingen (DE)

(21) Appl. No.: 18/808,888

(22) Filed: Aug. 19, 2024

(51) Int. Cl. H01L 21/66; H01L 21/50; H01L 21/67

(52) U.S. Cl. CPC H01L 22/12; H01L 21/50; H01L 21/67144

(57) ABSTRACT

A mask-to-donor alignment method for laser-induced forward transfer includes (a) directing a laser beam onto a mask to produce a masked beam including one or more separate sub-beams, each sub-beam being transmitted by a respective aperture of the mask, (b) viewing each sub-beam, as transmitted by a donor substrate carrying one or more devices, to obtain imagery indicating in each sub-beam a shadow of a corresponding one of the one or more devices, and (c) based on the imagery, adjusting position of the masked beam and the donor substrate, relative to each other, so as to align each device with respect to the corresponding sub-beam. This in-situ observation of the relative alignment between the donor substrate and the masked beam produces an improved alignment accuracy, as compared to the indirect fiducial-based alignment method. Alignment accuracies better than 0.2 μm, and associated sub-1 μm LIFT positioning accuracies, have been demonstrated.

### TECHNICAL FIELD OF THE INVENTION

The present invention relates to laser-induced forward transfer (LIFT) of one or more devices from a donor substrate to a receiver substrate, for example as applied to the manufacture of micro-light-emitting-diode (microLED) displays. The present invention relates in particular to techniques for ensuring that a masked laser beam, used to perform the LIFT process, is properly aligned with the device(s) on the donor substrate.

### DISCUSSION OF BACKGROUND ART

Consumers are continuously demanding thinner and lighter electronic devices with higher performance, such as thinner displays with higher resolution. To meet these demands, the microelectronics industry is pushing toward making ever smaller microelectronic devices. For example, microLEDs less than 50 micrometers (μm) by 50 μmin size and as small as about 5 μm by 5 μm are being developed for the purpose of making high-resolution LED displays. Such microLED displays are an emerging display technology expected to offer higher brightness, lower power consumption, and faster response than organic LED displays and liquid-crystal displays.

Wafer-level manufacturing has long been the most cost-effective mass-production method for microelectronic devices, with the capability to simultaneously manufacture millions of identical microelectronic devices on a single wafer. Wafer-level manufacturing of microelectronic devices and the process of implementing the microelectronic devices in a larger electronic device, such as a display, may involve one or more steps of transferring the microelectronic devices from one substrate to another. For example, the microelectronic devices may be grown at high density on a growth wafer and then implemented at lower density in a final device, possibly in conjunction with other types of microelectronic devices. The production of microelectronic devices also often involves processing of both the top and the bottom of the microelectronic devices after growing at least some layers of the microelectronic devices on a growth wafer. Such double-sided post-growth processing may require transferring the microelectronic devices to an intermediate carrier substrate in order to flip over the microelectronic devices. Additionally, pick-and-place technology may be used to replace faulty microelectronic devices on either a final substrate (e.g., a substrate with an active matrix) or an intermediate carrier substrate.

Within the context of wafer-level manufacturing, laser processing has several attractive properties such as non-contact mode of operation, selective and flexible application, and more easily managed environmental hazards than wet chemistry processing. Laser lift-off has emerged as a promising technology for transfer of microelectronic devices between two substrates. The laser lift-off process typically releases a microelectronic device from the donor substrate by laser ablating an intervening layer, such as gallium nitride or an adhesive. The intervening layer is located between the donor substrate and the microelectronic device or incorporated as a sacrificial layer of the microelectronic device itself. Laser lift-off may utilize ultraviolet light generated by an excimer laser, and a microelectronic device may be released from a substrate by a single laser pulse.

In a bond-release scheme, the microelectronic devices are bonded to the receiver substrate before being released from the donor substrate by laser ablation of the intervening layer. In a laser-induced forward transfer (LIFT) scheme, the receiver substrate is held a distance away from the microelectronic devices, and the laser ablation of the intervening layer not only releases the microelectronic devices from the donor substrate but also propels the microelectronic devices across the gap to the receiver substrate. When the intervening layer includes an adhesive, LIFT may be effected by laser ablation or by laser-induced vibration of the adhesive.

The greater distance between the donor and receiver substrates in LIFT may be advantageous or even required when transferring microelectronic devices to a receiver substrate that already contains other elements, e.g., already-deposited microelectronic devices. This situation is encountered during the positioning of microLEDs on a backplane of a microLED color-display, for example when red microLEDs are transferred to a microLED display backplane that already contains green and blue microLEDs. This situation is also encountered during repair processes that replace individual faulty microLEDs on the microLED display backplane.

In some embodiments, the laser beam effecting LIFT is incident on the microelectronic device with a flat-top intensity profile, at least for relatively small microelectronic devices. An asymmetric intensity profile and even Gaussian intensity profiles may cause the microelectronic device to rotate and/or travel sideways by some amount when crossing the gap between the donor and receiver substrates.

LIFT is often performed selectively to transfer one or more microelectronic devices, each located adjacent to other microelectronic devices that are not to be transferred. In such selective transfer, the incident laser beam is masked to irradiate the microelectronic device(s) to be transferred without irradiating the not-to-be-transferred microelectronic devices. Fiducials on the donor substrate are used to align the donor substrate relative to the masked laser beam. This fiducial-based alignment can yield an alignment accuracy of a few micrometers, although process drift when LIFT progresses through different areas of the donor substrate may lead to gradually growing deviations from the initial alignment accuracy.

### SUMMARY OF THE INVENTION

The continued push toward higher-resolution arrays of microelectronic devices, for example in microLED displays, drives an effort to reduce the sizes of individual microelectronic devices. At the same time, cost considerations motivate high utilization of the microelectronic-device growth wafers. Efficient utilization of the growth wafers entails minimizing the street width on the growth wafer, especially when the microelectronic devices are relatively small. A “street” is the unoccupied area between adjacent rows or columns of microelectronic devices.

The demand for smaller microelectronic devices and narrower streets has implications for transfers involved in the associated manufacturing processes. Situations are encountered where the distances between the microelectronic devices to be transferred and adjacent microelectronic devices not to be transferred are so small that only laser lift-off is feasible. LIFT remains the most attractive transfer technique in many cases. In some situations, LIFT is the only feasible transfer technique. However, it is challenging to align the donor substrate relative to the masked laser beam, effecting the LIFT process, with sufficient accuracy to meet the requirements presented by small sizes of the microelectronic devices and the streets therebetween. In addition to causing inadvertent irradiation of microelectronic devices that are not to be transferred, inaccuracies in this alignment process can lead to errors in landing location on the receiver substrate and/or breakage of the microelectronic device. Both a landing-location error and device breakage necessitate a subsequent targeted repair process.

Although it is possible to align fiducials to a high accuracy, this accuracy does not necessarily carry over to the actual microelectronic devices. Thus, when relying on fiducials for the alignment between the donor substrate and the masked laser beam, it may be necessary to evaluate the outcome of an initial transfer of a few microelectronic devices and make adjustments accordingly, before proceeding with the actual transfer process. Such evaluation entails inspecting the receiver substrate under a microscope and thus necessitates temporarily removing the receiver substrate from the transfer apparatus. This is a time-consuming step and results in poor utilization of the transfer apparatus. Even if accepting this loss of efficiency, fiducial-based alignment may simply lack the accuracy required to properly and accurately transfer a microelectronic device via LIFT without irradiating adjacent microelectronic devices.

Disclosed herein is a method for aligning the donor substrate and the masked laser beam to each other that utilizes in-situ observation of the relative alignment between the donor substrate and the masked laser beam to achieve an improved alignment accuracy, as compared to the indirect fiducial-based alignment method. The presently disclosed alignment method does not rely on sacrificial transfers of microelectronic devices for alignment evaluation in a separate instrument. Instead, the alignment method directly views the laser radiation transmitted by the mask and the donor substrate. This viewing may be accomplished with a beam profiler. The captured imagery shows any fraction of the masked laser beam transmitted by the donor substrate and not blocked by microelectronic devices on the donor substrate. When the masked laser beam is incident on a microelectronic device to be transferred, the microelectronic device produces a shadow that partly or fully blocks the masked laser beam. Based on the captured imagery, the positioning of the donor substrate and/or the masked laser beam is adjusted to align the microelectronic device relative to the masked laser beam. Alignment accuracies better than 0.2 μm have been demonstrated with the present method. Such alignment accuracies can be maintained over simultaneous or sequential transfer of many microelectronic devices. Aided by these alignment accuracies, LIFT can be performed with sub-1 μm positioning accuracies.

In one aspect of the invention, a mask-to-donor alignment method for laser-induced forward transfer includes a step of directing a laser beam onto a mask to produce a masked laser beam including one or more separate sub-beams. Each sub-beam is transmitted by a respective aperture of the mask. The mask-to-donor alignment method also includes a step of viewing each sub-beam, as transmitted by a donor substrate carrying one or more devices, to obtain imagery indicating in each sub-beam a shadow of a corresponding one of the one or more devices. Additionally, the mask-to-donor alignment method includes a step of, based on the imagery, adjusting position of the masked laser beam and the donor substrate, relative to each other, so as to align each device with respect to the corresponding sub-beam.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIG. 1 illustrates a mask-to-donor alignment method to aid LIFT, according to an embodiment. FIG. 1 also illustrates a transfer process that incorporates the mask-to-donor alignment method and a LIFT method, according to an embodiment.

FIG. 2 is a schematic perspective view that illustrates viewing of a masked beam by a beam profiler in the alignment method of FIG. 1, according to an embodiment.

FIGS. 3A and 3B show exemplary images obtained by the beam profiler in the alignment method of FIG. 1.

FIG. 4 is an image captured by a beam profiler upon completion of one example of the alignment method of FIG. 1.

FIG. 5 is an image captured by a beam profiler upon completion of another example of the alignment method of FIG. 1.

FIG. 6 illustrates an adjustment scheme that may be employed by the alignment method of FIG. 1, according to an embodiment.

FIG. 7 illustrates a laser transfer apparatus configured to perform the transfer process of FIG. 1, according to an embodiment.

FIG. 8 illustrates a mask-to-donor alignment method for LIFT-based mass-transfer of a plurality of devices from a donor substrate to a receiver substrate, according to an embodiment.

FIG. 9 is an example image captured by a beam profiler during the alignment method of FIG. 8, in a situation where there is a lateral translation error between the mask and the donor substrate.

FIG. 10 is an example image captured by a beam profiler during the alignment method of FIG. 8, in a situation where there is a lateral rotation error between the mask and the donor substrate.

FIG. 11 illustrates a laser transfer apparatus configured to image a mask onto a donor substrate, according to an embodiment.

FIG. 12 is an example image captured by a beam profiler in the FIG. 11 apparatus during the FIG. 8 alignment method, in a situation where there is a (de)magnification error between the mask and the donor substrate.

FIG. 13 is an example image captured by a beam profiler indicating a defective device.

FIG. 14 is a flowchart for a mask-to-donor alignment method to aid LIFT, according to an embodiment.

FIG. 15 is a flowchart for a laser transfer method that utilizes the alignment method of FIG. 14, according to an embodiment.

FIG. 16 is a flowchart for a mask-to-donor alignment method to aid mass-transfer of a plurality of devices via LIFT, according to an embodiment.

### DETAILED DESCRIPTION OF THE INVENTION

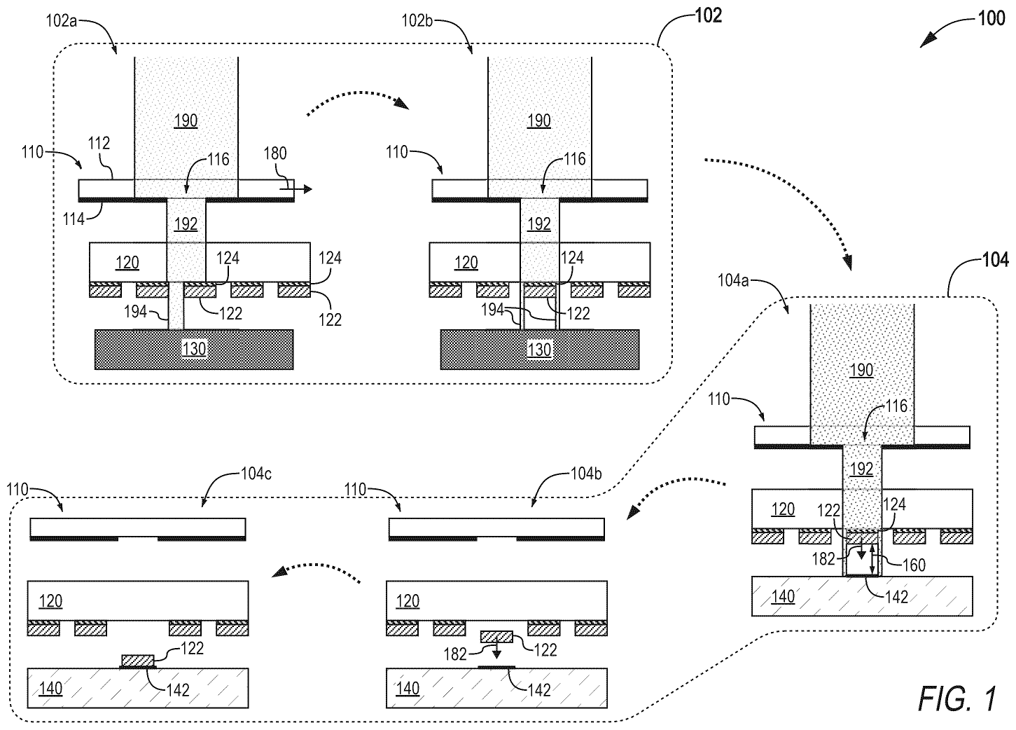

Referring now to the drawings, wherein like components are designated by like numerals, FIG. 1 illustrates one mask-to-donor alignment method 102 to aid LIFT. FIG. 1 also illustrates one transfer process 100 that incorporates alignment method 102 and a LIFT method 104. Alignment method 102 is illustrated by cross-sectional diagrams 102a and 102b. LIFT method 104 is illustrated by cross-sectional diagrams 104a, 104b, and 104c. In the following, alignment method 102 is discussed within the context of transfer process 100. The objective of transfer process 100 is to transfer a microelectronic device 122 from a donor substrate 120 to a receiver substrate 140 via LIFT. Device 122 may be a microLED. LIFT is effected by a masked laser beam 192 produced by directing a laser beam 190 onto a mask 110. Alignment method 102 serves to align masked beam 192 and the to-be-transferred device 122 to each other.

In the depicted scenario, donor substrate 120 carries a plurality of devices 122, one of which is to be transferred. In an alternative scenario, donor substrate 120 does not include devices 122 other than the one to be transferred. However, alignment method 102 has particular advantages in scenarios where the device to be transferred is located close to other devices on the donor substrate. Thus, the following discussion assumes that donor substrate 120 carries a plurality of devices 122.

Donor substrate 120 may be a growth wafer for devices 122, or an intermediate carrier. In either case, an intervening layer 124 connects each device 122 to donor substrate 120. Intervening layer 124 may be a sacrificial portion of device 122. In one embodiment, donor substrate 120 is a growth substrate for devices 122. In this embodiment, masked beam 192 may effect LIFT by ablating intervening layer 124, and intervening layer 124 may be made of gallium nitride. In another embodiment, donor substrate 120 is an intermediate carrier. In this embodiment, devices 122 are typically secured to an adhesive layer (not shown in FIG. 1) on donor substrate 120, and masked beam 192 may effect LIFT through the same mechanism as when donor substrate 120 is a growth substrate. Alternatively, when devices 122 are secured to an adhesive layer on donor substrate 120, intervening layer 124 may be a local portion of the adhesive layer at the interface between device 122 and donor substrate 120. When intervening layer 124 includes an adhesive, LIFT may be effected by (a) ablating the adhesive layer at the local interface between the to-be-transferred device 122 and donor substrate 120 or (b) causing the adhesive layer to vibrate at this interface.

Receiver substrate 140 may be a final substrate for device 122 or an intermediate carrier. In the former case, receiver substrate 140 may include an electrical contact pad 142 for device 122, as shown in FIG. 1. In one such example, device 122 is a microLED, and receiver substrate 140 is a display backplane. When receiver substrate 140 is an intermediate carrier, receiver substrate 140 may include an adhesive layer (not depicted in FIG. 1) that bonds device 122 to receiver substrate 140 after LIFT.

Mask 110 has a light-transmitting aperture 116. In the depicted embodiment, mask 110 includes a substrate 112 with a layer 114 deposited thereon, and aperture 116 is formed in layer 114. Layer 114 is opaque at the wavelength of laser beam 190. Laser beam 190 may be ultraviolet. Regardless of how aperture 116 is defined in mask 110, aperture 116 is sized such that masked beam 192 can irradiate intervening layer 124, connecting the to-be-transferred device 122 to donor substrate 120, without irradiating intervening layers 124 connecting other adjacent devices 122 to donor substrate 120. However, proper sizing of aperture 116 is not in itself sufficient to achieve this irradiation configuration. In addition, masked beam 192 must be aimed at the to-be-transferred device 122. This task is performed by alignment method 102.

Alignment method 102 views masked beam 192, as transmitted by donor substrate 120 with its devices 122. Alignment method 102 may view masked beam 192 with a beam profiler 130. Beam profiler 130 may include an image sensor, a camera, or a scanning photodetector. When at least a portion of masked beam 192 is incident on the to-be-transferred device 122, as shown in diagram 102a, beam profiler 130 obtains imagery that shows a fraction 194 of masked beam 192 transmitted by donor substrate 120. The imagery of transmitted beam fraction 194 indicates a shadow of the to-be-transferred device 122 in masked beam 192. In the depicted example, aperture 116 is sized to produce “overshoot”. The term “overshoot” refers to masked beam 192 having a larger footprint than the to-be-transferred device 122 on donor substrate 120. Thus, a fraction 194 of masked beam 192 reaches beam profiler 130 even if to-be-transferred device 122 is centered in masked beam 192. Based on the obtained imagery, alignment method 102 adjusts the position of masked beam 192 and/or donor substrate 120 to align the to-be-transferred device 122 with respect to the masked beam 192, as shown in diagram 102b. In one scenario, to-be-transferred device 122 is considered aligned with respect to the masked beam 192 when to-be-transferred device 122 is (a) entirely within masked beam 192 and/or (b) centered with respect to masked beam 192. Herein, centering refers to two-dimensional centering.

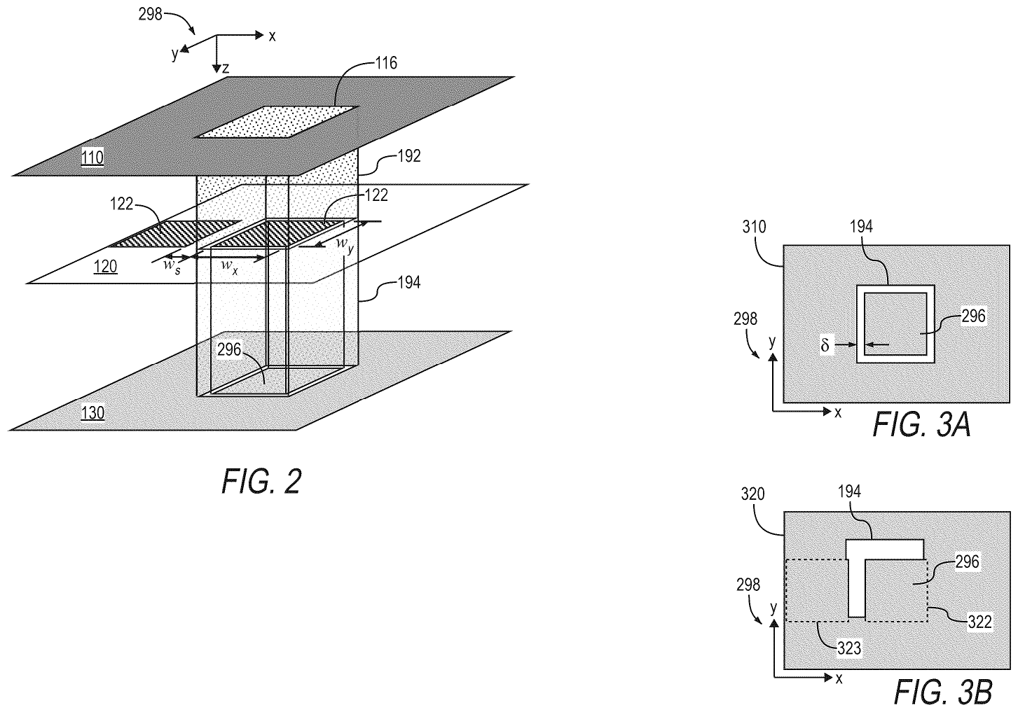

FIG. 2 is a schematic, perspective view that illustrates, in further detail, viewing of masked beam 192 by beam profiler 130 in alignment method 102. FIGS. 3A and 3B show respective images 310 and 320 obtained by beam profiler 130. FIGS. 2, 3A, and 3B are best viewed together. FIGS. 2, 3A, and 3B depict two devices 122 on donor substrate 120. One of these devices is to be transferred by LIFT method 104. Although not depicted in FIGS. 2, 3A, and 3B, to-be-transferred device 122 may be one device in a two-dimensional array of devices 122 on donor substrate, in which case to-be-transferred device 122 may be surrounded by other devices 122.

Each device 122 has orthogonal transverse dimensions wₓ and w_{y}. Transverse dimensions wₓ and w_{y} may be less than 100 μm, for example in the range between 3 and 50 μm. To-be-transferred device 122 is a separation distance wₛ away from each nearest-neighbor device 122. Separation distance wₛ may represent a street width. In one example, separation distance wₛ is less than 10 μm, e.g., in the range between 3 and 10 μm. In this example, one or both of transverse dimensions wₓ and w_{y} may be less than 50 μm, e.g., in the range between 3 and 25 μm.

When the to-be-transferred device 122 is centered in masked beam 192 and aperture 116 is sized to produce “overshoot”, beam profiler 130 obtains image 310 (see FIG. 3A). To-be-transferred device 122 casts a shadow 296, which is apparent in transmitted beam fraction 194 in image 310. Transmitted beam fraction 194 surrounds shadow 296. Image 320 (see FIG. 3B) is an example of an image obtained while the to-be-transferred device 122 and masked beam 192 are not properly aligned relative to each other. In image 320, masked beam 192 fails to irradiate the complete footprint of device 122. This is evident from the fact that transmitted beam fraction 194 does not surround shadow 296. For clarity of illustration, the complete outline 322 of shadow 296 is indicated in FIG. 3B. Additionally, masked beam 192 overlaps with an adjacent device 122 that is not to be transferred, as evident from a second shadow (indicated by outline 323) infringing on transmitted beam fraction 194.

Depending on the application, overshoot may or may not be permissible. For example, overshoot may need to be eliminated or at least minimized when receiver substrate 140 contains elements susceptible to damage if irradiated by masked beam 192 during LIFT method 104. Such scenarios may be encountered when (a) receiver substrate 140 is a display backplane and/or (b) when LIFT method 104 is used in a repair process to replace a faulty or missing device of a device array. Overshoot may be minimized by sizing aperture 116 to exactly match the footprint of masked beam 192 on donor substrate to that of device 122, e.g., to within 0.4 μm or 0.2 μm. In the absence of overshoot, alignment method 102 may adjust the relative positioning of masked beam 192 and donor substrate 120 until device 122 completely or substantially blocks masked beam 192, as assessed from imagery obtained by beam profiler 130. Diffraction and/or other minor imperfections may lead to a small fraction of masked beam 192 being detected by beam profiler 130.

Referring again to FIG. 1, alignment method 102 may adjust the relative positions of masked beam 192 and donor substrate 120 by moving (a) mask 110, e.g., as indicated by arrow 180, (b) donor substrate 120, and/or (c) one or more optional optical elements (not depicted in FIG. 1) that relay masked beam 192 from mask 110 to donor substrate 120. Such movement may entail lateral translation and/or rotation. The lateral translation/rotation is in a plane orthogonal to the propagation direction of masked beam 192 (e.g., parallel to the xy-plane indicated by cartesian coordinate system 298 in FIG. 2).

Hereinafter, reference to x-, y-, and z-axes and associated dimensions and planes refer to coordinate system 298. The z-axis is generally orthogonal to the donor substrate and parallel to the propagation direction of the masked beam as incident on the donor substrate.

Once alignment method 102 is completed, transfer process 100 can proceed to LIFT method 104. As shown in diagram 104a, receiver substrate 140 is positioned to face the surface of donor substrate 120 carrying devices 122, with a non-zero gap 160 between the to-be-transferred device 122 and receiver substrate 140. Fiducials may be used to align receiver substrate 140 relative to donor substrate 120. Beam profiler 130 may be removed to make room for receiver substrate 140. In certain embodiments, however, the distance between beam profiler 130 and donor substrate 120 is sufficiently large that beam profiler 130 can be left in place during LIFT method 104.

As illustrated in the sequence of diagrams 104a, 104b, and 104c, masked beam 192 irradiates intervening layer 124. The power of masked beam 192 used in LIFT method 104 typically exceeds the power of masked beam 192 used in alignment method 102 by a significant amount. In LIFT method 104, the irradiation by masked beam 192 releases the to-be-transferred device 122 from donor substrate 120 and propels the to-be-transferred device 122 away from donor substrate 120, as indicated by arrow 182 in diagrams 104a and 104b. The to-be-transferred device 122 thereby crosses gap 160 and lands on receiver substrate 140, as shown in diagram 104c.

A misalignment between masked beam 192 and the to-be-transferred device 122 can cause LIFT method 104 to fail. The outcome of LIFT method 104 is usually significantly more sensitive to misalignment between donor substrate 120 and masked beam 192 than to misalignment between receiver substrate 140 and donor substrate 120. Whereas, in most instances, fiducial-based alignment suffices for the alignment of receiver substrate 140 relative to donor substrate 120, higher accuracy may be required for the alignment of donor substrate 120 relative to masked beam 192. A certain error in the alignment of receiver substrate 140 relative to donor substrate 120 results in a positioning error of the same size for device 122 on receiver substrate. In contrast, misalignment between donor substrate 120 and masked beam 192 can cause damage or a substantial error in the positioning of device 122 on receiver substrate 140. If a portion of intervening layer 124 is not irradiated by masked beam 192, device 122 may (a) fail to release from donor substrate 120, (b) break upon release from donor substrate, or (c) fully release but undergo rotation during travel toward receiver substrate 140. If device 122 rotates during travel, device 122 may land on receiver substrate 140 away from the intended landing location and/or break upon landing. Inadvertent irradiation of a portion of the intervening layer 124 associated with an adjacent device 122 may compromise subsequent LIFT of this adjacent device 122.

The alignment accuracy required for successful completion of LIFT method 104 depends on several factors, including the extent to which overshoot is permissible, the distance (e.g., street width) between adjacent devices 122, and the intensity profile of masked beam 192. Scenarios where overshoot must be minimized are particularly demanding in terms of alignment accuracy, especially when the transverse dimensions of devices 122 are small. Using FIGS. 2 and 3A as a visual example, consider an example where overshoot δ (see FIG. 3A) needs to be minimized and each of transverse dimensions wₓ and w_{y} (see FIG. 2) of device 122 is less than 10 μm. In this example, sub-1 μm alignment accuracy may be required and are achievable. In fact, sub-0.2 μm alignment accuracies have been demonstrated with alignment method 102.

When overshoot is permissible, it may be possible to relax the alignment accuracy. Still, when there are multiple devices 122 on donor substrate, the distance between adjacent device 122, e.g., street width wₛ (see FIG. 2), limits the allowable alignment error. For example, a street width wₛ of less than 5 μm typically necessitates sub-5 μm alignment accuracy in order to prevent irradiation of adjacent devices 122 that are not to be transferred. Better alignment accuracy may be required to position to-be-transferred device 122 within a particular portion of the transverse intensity profile of masked beam 192. Preferably, masked beam 192 has a substantially flat-top intensity profile at donor substrate 120. The flat-top intensity profile facilitates substantially uniform irradiation of intervening layer 124 and thereby even release of to-be-transferred device 122 in LIFT method 104. However, the edges of the flat-top intensity profile, where the intensity drops from the flat-top level to zero, have non-zero width. Thus, preferably, alignment method 102 keeps to-be-transferred device 122 within the flat-top portion while keeping the surrounding edges of the flat-top portion away from adjacent devices 122. In one example, each transverse dimension wₓ and w_{y} of device 122 is 5 μm, street width wₛ is 5 μm, and the width of the edges of the flat-top intensity profile is 2 μm. In this example, sub-1 μm alignment accuracy is preferred. More generally, alignment method 102 may be configured to achieve an alignment accuracy that is significantly better than the distance between adjacent devices 122 in order to account for non-uniformity of the intensity profile of masked beam 192.

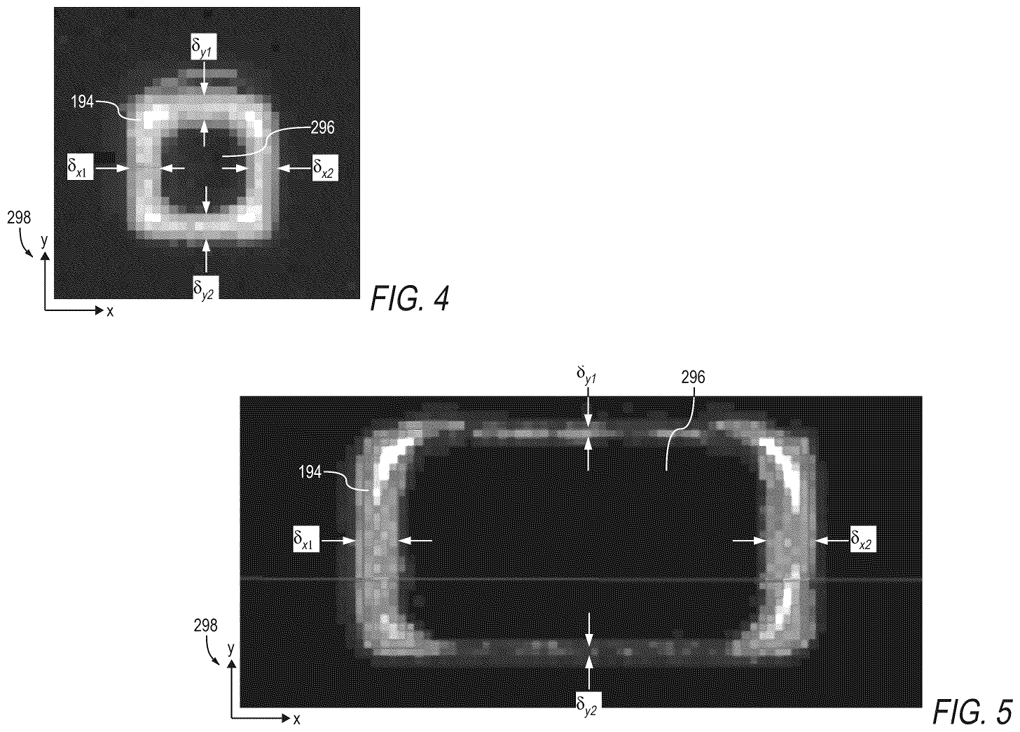

FIG. 4 is an image captured by beam profiler 130 upon completion of one example of alignment method 102. In this example, device 122 is square with 5 μm side lengths, and alignment method 102 is performed with overshoot, resulting in a situation similar to that depicted in FIG. 3A. Masked beam 192 has a square flat-top transverse intensity profile. The flat-top portion of masked beam 192 has 5 μm side lengths and is surrounded by a 1.5 μm wide edge where the laser intensity drops from the flat-top level to zero. Transmitted beam fraction 194 surrounds shadow 296. Alignment method 102 has maximized the symmetry of the overshoot on opposite sides of shadow 296, such that x-dimension overshoot widths δₓ₁ and δₓ₂ are substantially identical, and y-dimension overshoot widths δ_{y1} and δ_{y2} are substantially identical. In this example, alignment method 102 was capable of centering device 122 in masked beam 192 with sub-0.2 μm accuracy, and subsequent LIFT method 104 was performed with sub-1 μm positioning accuracies of device 122 on the receiver substrate.

FIG. 5 is an image captured by beam profiler 130 upon completion of another example of alignment method 102. In this example, device 122 is a 20 μm×10 μm rectangular device, alignment method 102 is again performed with overshoot, and masked beam 192 has a rectangular flat-top transverse intensity profile. Also in this example, alignment method 102 has maximized the symmetry of the overshoot on opposite sides of shadow 296, such that x-dimension overshoot widths δₓ₁ and δₓ₂ are substantially identical, and y-dimension overshoot widths δ_{y1} and δ_{y2} are substantially identical. Alignment method 102 was capable of centering device 122 in masked beam 192 with sub-0.2 μm accuracy also in this example.

The examples depicted in each of FIG. 2-5 benefit from overshoot. The overshoot makes it relatively straightforward to ascertain when device 122 is centered in masked beam 192. In the absence of overshoot, substantially no portion of masked beam 192 is viewable by beam profiler 130 when device 122 is centered in masked beam 192. In practice, a tail of the transverse intensity distribution of masked beam 192 may pass by the perimeter of device 122 and reach beam profiler 130. For example, when masked beam 192 has a flat-top profile, an edge of masked beam 192 where the intensity drops from the flat-top level to zero may pass by device 122. When the flat-top portion of masked beam 192 is sized to match the transverse dimensions of device 122, this edge may be detected by beam profiler 130 and may be used to assess the alignment between masked beam 192 and device 122. When one or more transverse dimensions of intervening layer 124 are smaller than the corresponding transverse dimensions of device 122, even the edge of masked beam 192 may be blocked by device 122. The intensity detected by beam profiler 130 may be compared to an intensity threshold, and detected intensities lower than the intensity threshold may be rounded to zero or ignored.

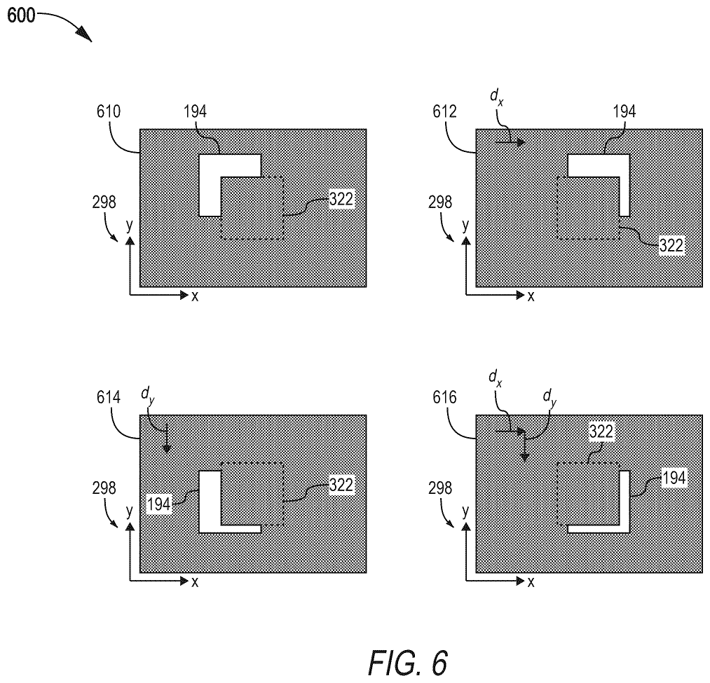

FIG. 6 illustrates one adjustment scheme 600 that may be employed by alignment method 102. Adjustment scheme 600 is particularly useful when operating without overshoot, for example when a flat-top portion of masked beam 192 is either the same size or smaller than the transverse dimensions of device 122. In adjustment scheme 600, mask 110 (see FIG. 1) is translated laterally by known distances in the xy-plane to position mask 110 at a series of different locations. Each mask location corresponds to a different lateral offset relative to donor substrate 120. For each mask location, masked beam 192 and device 122 are deliberately misaligned relative to each other, such that a transmitted beam fraction 194 reaches beam profiler 130. Beam profiler 130 captures an image for each mask location. The xy-coordinates of each mask location is known relative to a reference location of mask 110. The reference location is, for example, the first location of mask 110 in the series of locations. The location of mask 110, that corresponds to masked beam 192 and device 122 being aligned relative to each other, is derived from the images captured by beam profiler 130.

In the example depicted in FIG. 6, adjustment scheme 600 utilizes four different locations for mask 110, and beam profiler 130 captures corresponding images 610, 612, 614, and 616. Taking the position of mask 110 associated with image 610 as the reference location, mask 110 is translated by (a) a distance dₓ in the x-dimension to produce image 612, (b) a distance d_{y} in the y-dimension to produce image 614, and (c) distances dₓ and d_{y} to produce image 616. Due to the deliberate misalignment between masked beam 192 and device 122 in each of images 610, 612, 614, and 616, a transmitted beam fraction 194 is visible in each image. From these images, it is possible to calculate the xy-coordinates of mask 110 corresponding to masked beam 192 and device 122 being aligned relative to each other. More generally, three different locations of mask 110 may suffice, provided that these locations are not colinear.

In a modification of scheme 600, donor substrate 120 is translated instead of mask 110. The images captured by beam profiler 130 contain the same information about the alignment between masked beam 192 and device 122 as those obtained when mask 110 is being translated.

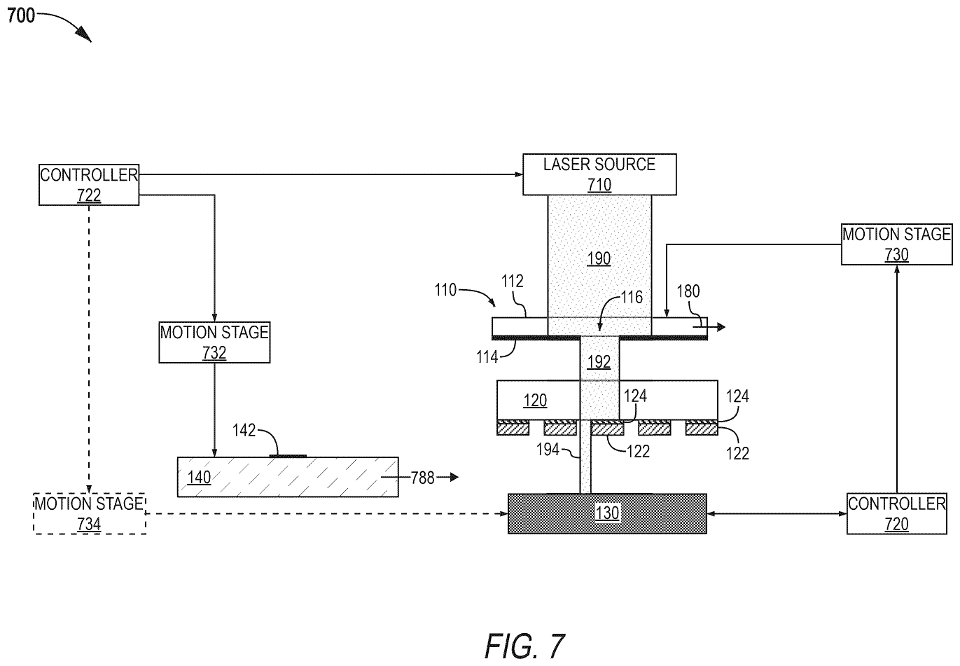

FIG. 7 illustrates one laser transfer apparatus 700 configured to perform transfer process 100. Apparatus 700 includes beam profiler 130, a laser source 710, controllers 720 and 722, motion stages 730 and 732, and, optionally, a motion stage 734. Apparatus 700 is configured to receive mask 110, donor substrate 120, and receiver substrate 140, discussed above in reference to FIG. 1. Motion stages 730 and 732 are coupled to mask 110 and receiver substrate 140, respectively. Motion stage 734, if included, is coupled to beam profiler 130. Controller 720 is communicatively coupled between beam profiler 130 and motion stage 730. Controller 722 is communicatively coupled to laser source 710 and motion stage 732, as well as motion stage 734 if included. Controllers 720 and 722 may be implemented in a single controller. When controllers 720 and 722 are implemented separately, a master controller (not depicted) may coordinate the operation of controllers 720 and 722.

When apparatus 700 is operated to perform alignment method 102, controller 722 commands laser source 710 to generate laser beam 190 with a power too low for to-be-transferred device 122 to be released from donor substrate 120. Controller 720 commands beam profiler 130 to capture one or more images and receives the captured image(s) from beam profiler 130. Based on this imagery, controller 720 commands motion stage 730 to translate and/or rotate mask 110 (e.g., as indicated by arrow 180) so as to align the to-be-transferred device 122 and masked beam 192 with each other, as discussed above in reference to FIG. 1-6. A human operator may aid controller 720 in analyzing the imagery obtained from beam profiler 130.

Without departing from the scope hereof, motion stage 730 may instead be coupled to donor substrate 120 so as to translate/rotate donor substrate 120 as needed to align masked beam 192 and donor substrate 120. Additionally, in an embodiment not depicted in FIG. 7, laser apparatus 700 includes one or more optical elements that relay masked beam 192 from mask 110 to donor substrate 120. In this embodiment, motion stage 730 may be coupled to one or more of these optical elements to effect translation and/or rotation of masked beam 192 relative to donor substrate 120.

When apparatus 700 is operated to perform LIFT method 104, controller 722 commands motion stage 732 to shift receiver substrate 140 into the position required for the LIFT process, as indicated by arrow 788. In the depicted scenario, motion stage 732 positions receiver substrate 140 such that device 122 will land on contact pad 142. Although not shown in FIG. 7, apparatus 700 may include one or more cameras configured to image fiducials on receiver substrate 140 and donor substrate 120, so as to ensure that receiver substrate 140 is aligned with donor substrate 120. In embodiments where beam profiler 130 is in the way of receiver substrate 140, controller 722 commands motion stage 734 to shift beam profiler 130 out of the way before motion stage 732 shifts receiver substrate 140 into the positioned required for the LIFT process. After positioning receiver substrate 140 to receive device 122, controller 722 commands laser source 710 to generate laser beam 190 with a power sufficient for masked beam 192 to effect LIFT of device 122 from donor substrate 120 to receiver substrate 140, as discussed above in reference to FIG. 1.

Referring again to FIG. 1, the alignment achieved in alignment method 102 may be applied to sequential LIFT of a plurality of devices 122 from donor substrate 120 to receiver substrate 140 when the relative coordinates of these devices 122 on donor substrate 120 are known. In one such extension of transfer process 100, alignment method 102 and LIFT method 104 are applied to a first device 122 as discussed above in reference to FIG. 1. Next, masked beam 192 is translated relative to donor substrate 120 to aim masked beam 192 at a second device 122 on donor substrate 120 and transfer this second device 122 to receiver substrate 140. The translation of masked beam 192 relative to donor substrate 120 may be achieved by translating mask 110 or donor substrate 120, or by adjusting one or more optical elements (not depicted in FIG. 1) configured to relay masked beam 192 from mask 110 to donor substrate 120. When the translation is applied to donor substrate 120, receiver substrate 140 may be translated as well so as to maintain the same positional relationship between donor substrate 120 and receiver substrate 140. The translation imposed to aim masked beam 192 at the second device 122 matches a known difference in the coordinates of the first and second devices 122 on donor substrate 120. In this manner, the alignment achieved by applying alignment method 102 to the first device 122 can be extrapolated to a plurality of other devices 122 on donor substrate 120 to be transferred by LIFT method 104 in a sequential fashion, e.g., scanning.

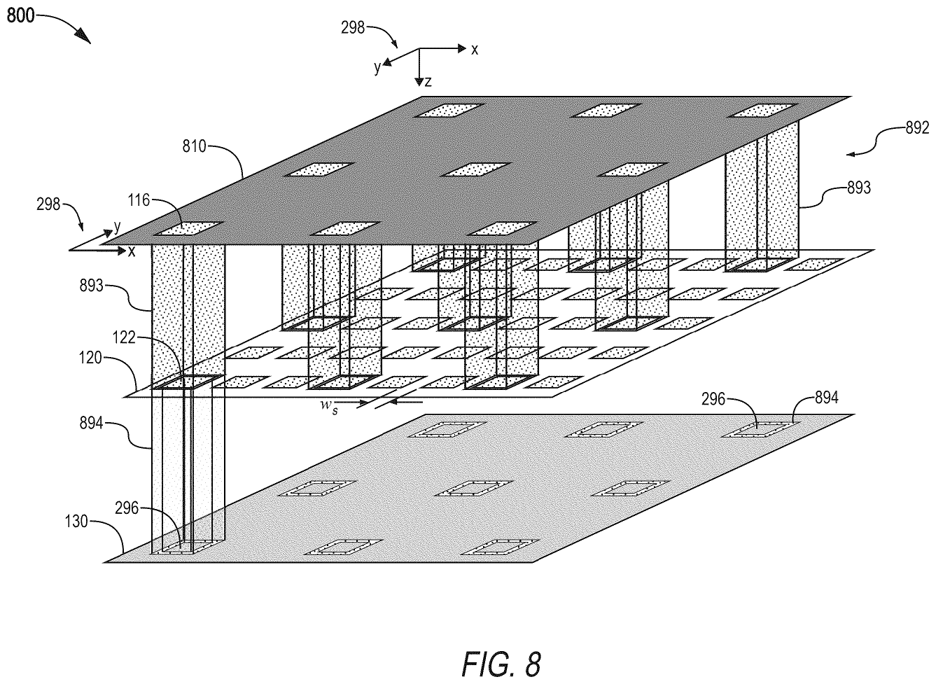

FIG. 8 is a diagram that illustrates one mask-to-donor alignment method 800 for LIFT-based mass-transfer of a plurality of devices 122 from donor substrate 120 to receiver substrate 140. Alignment method 800 collectively aligns the plurality of to-be-transferred devices 122 to a masked laser beam 892 that includes a respective plurality of separate sub-beams 893. Alignment method 800 is an extension of alignment method 102, wherein mask 110 is replaced by a mask 810 having a plurality of apertures 116 to facilitate mass-transfer. Alignment method 800 is similar to alignment method 102 except that alignment method 800 (a) utilizes mask 810 and (b) collectively considers the alignment between the plurality of sub-beams 893 and the plurality of to-be-transferred devices 122 on donor substrate 120.

When mask 810 is placed in the path of laser beam 190 (as shown for mask 110 in FIG. 1), each aperture 116 transmits a respective sub-beam 893. The positional layout of apertures 116 of mask 810 at least nominally matches the positional layout of the to-be-transferred devices 122 on donor substrate 120. Donor substrate 120 may carry other devices 122 that are not to be transferred. The objective of alignment method 800 is to align donor substrate 120 relative to masked beam 892 in such a way that each to-be-transferred device 122 is aligned with a respective sub-beam 893. In the example depicted in FIG. 8, donor substrate 120 carries a plurality of devices 122 arranged in a two-dimensional regular array. A subset of these devices 122 are to be transferred, in this example specifically every third device 122 from every other row.

Alignment method 800 utilizes imagery captured by beam profiler 130 to evaluate the alignment between the plurality of to-be-transferred devices 122 and masked beam 892. Alignment method 800 relies on fractions 894 of respective sub-beams 893 detected by beam profiler 130 to evaluate the alignment between sub-beams 893 and to-be-transferred devices 122. Based on the imagery obtained by beam profiler 130, alignment method 800 adjusts the relative positioning of mask 810 and donor substrate 120 in a manner similar to that discussed above for alignment method 102.

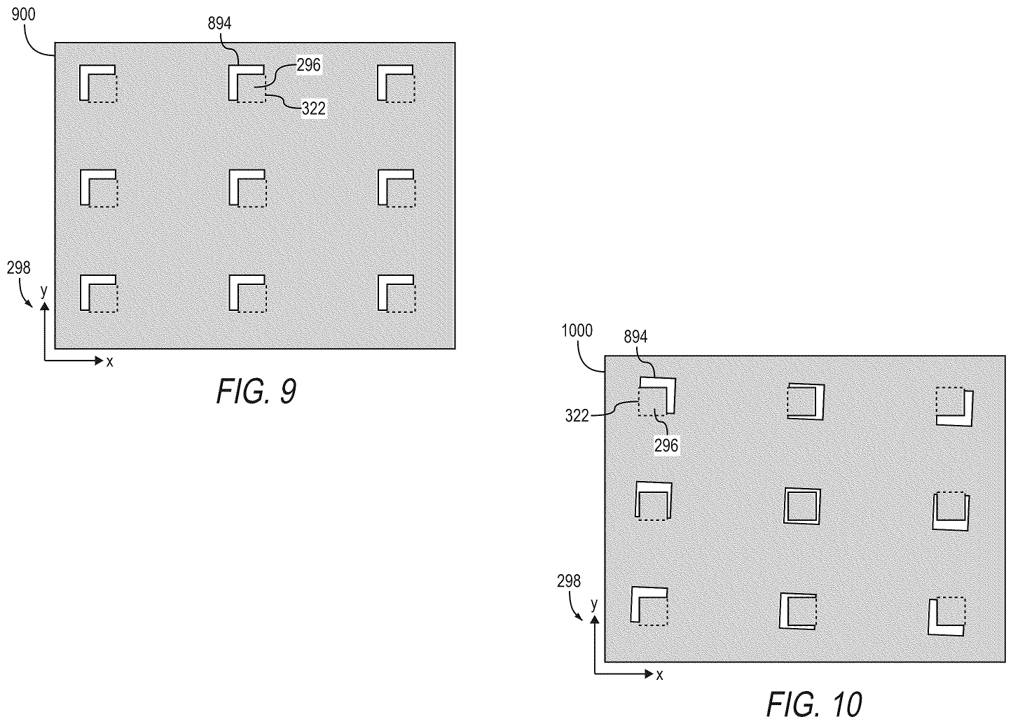

Alignment method 800 is compatible with both overshoot and no overshoot. In the depicted scenario, apertures 116 are sized to produce overshoot. FIGS. 9 and 10, discussed below, illustrate potential forms of misalignment that can be corrected with alignment method 800, in scenarios with overshoot. In the absence of overshoot, alignment method 800 may employ a scheme similar to adjustment scheme 600 but extended to collective consideration of the plurality of to-be-transferred device 122.

FIG. 9 is an example image 900 captured by beam profiler 130 during alignment method 800, in a situation where there is a lateral translation error between mask 810 and donor substrate 120. A transmitted beam fraction 894 is visible for each device 122. The outline 322 of shadow 296 of each device 122 is indicated for illustrative purposes. Devices 122 are not centered in the respective sub-beams 893, as evidenced by the asymmetric nature of each transmitted beam fraction 894. The asymmetry is the same for each transmitted beam fraction 894, indicative of a lateral positioning error between mask 810 and donor substrate 120.

FIG. 10 is an example image 1000 captured by beam profiler 130 during alignment method 800, in a situation where there is a lateral rotation error between mask 810 and donor substrate 120. The rotation error is evident from the pattern formed by transmitted beam fractions 894.

Referring again to FIG. 8, alignment method 800 collectively considers the plurality of transmitted beam fractions 894 visible in imagery obtained by beam profiler 130. This collective consideration may entail minimizing an average displacement between sub-beams 893 and the respective to-be-transferred devices 122, or minimizing or eliminating displacements in excess of a desired/acceptable displacement limit. In situations where there is some imperfection in the actual positioning of to-be-transferred devices 122 on donor substrate 120 and/or in the actual positioning, shape, or size of apertures 116 in mask 810, it may not be possible to perfectly center each to-be-transferred device 122 in the corresponding sub-beam 893.

Optionally, alignment method 800 includes evaluating imagery captured by beam profiler 130 in an optimally aligned configuration to determine if one or more devices 122 fail to meet an alignment requirement. However, provided that there are no significant positioning errors of to-be-transferred device 122 on donor substrate 120 and no significant positioning/shape/size errors of apertures 116 in mask 810, alignment method 800 is capable of sub-1 μm alignment accuracy for each individual to-be-transferred device 122 in the corresponding sub-beam 893.

Once alignment method 800 has aligned sub-beams 893 and the plurality of to-be-transferred devices 122 relative to each other, the to-be-transferred devices 122 may be transferred by a mass-transfer equivalent of LIFT method 104. In this mass-transfer equivalent of LIFT method 104, masked beam 892 simultaneously effects LIFT of the plurality of to-be-transferred devices 122 from donor substrate 120 to receiver substrate 140. The transfer mechanism for each individual to-be-transferred device 122 is similar to that discussed above in reference to FIG. 1 and LIFT method 104.

In some embodiments, not all devices 122 to be transferred in a single mass-transfer are within the field view of beam profiler 130. This issue can be remedied by translating beam profiler 130 to capture a series of images at different locations. Alternatively or in combination therewith, alignment method 800 may rely on incomplete imagery from beam profiler 130 that samples only a subset of the to-be-transferred devices 122. In such instances, high alignment accuracy may render the transfer process less prone to failures caused by misalignment between non-sampled to-be-transferred devices 122 and their respective sub-beams 893. Generally, high alignment accuracy for the to-be-transferred devices 122 that are actually sampled by the imagery obtained by beam profiler 130 may serve to optimally center the alignment of all to-be-transferred devices 122 in a processing window that is subject to a variety of tolerances. High alignment accuracy may be similarly helpful if the alignment achieved by alignment method 800 is extrapolated to another set of devices 122 on donor substrate 120 that are to be transferred in a subsequent mass-transfer.

Apparatus 700 may perform alignment method 800 in a manner similar the performance of alignment method 102, except that controller 720 considers a plurality of transmitted beam fractions 894 to evaluate and adjust the alignment between masked beam 892 and donor substrate 120. Utilizing the alignment achieved by alignment method 800, apparatus 700 may perform the mass-transfer equivalent of LIFT method 104 discussed above.

As discussed within the context of alignment method 102, beam profiler 130 may provide additional information within the context of alignment method 800, such as evaluating the imagery for defective/missing devices 122 and performing a post-LIFT check with masked beam 892 to check if LIFT was successful for all to-be-transferred devices.

Alignment method 102 may be viewed as a reduction of alignment method 800, wherein mask 810 produces only a single sub-beam 893 to be aligned with a single device 122 on donor substrate 120.

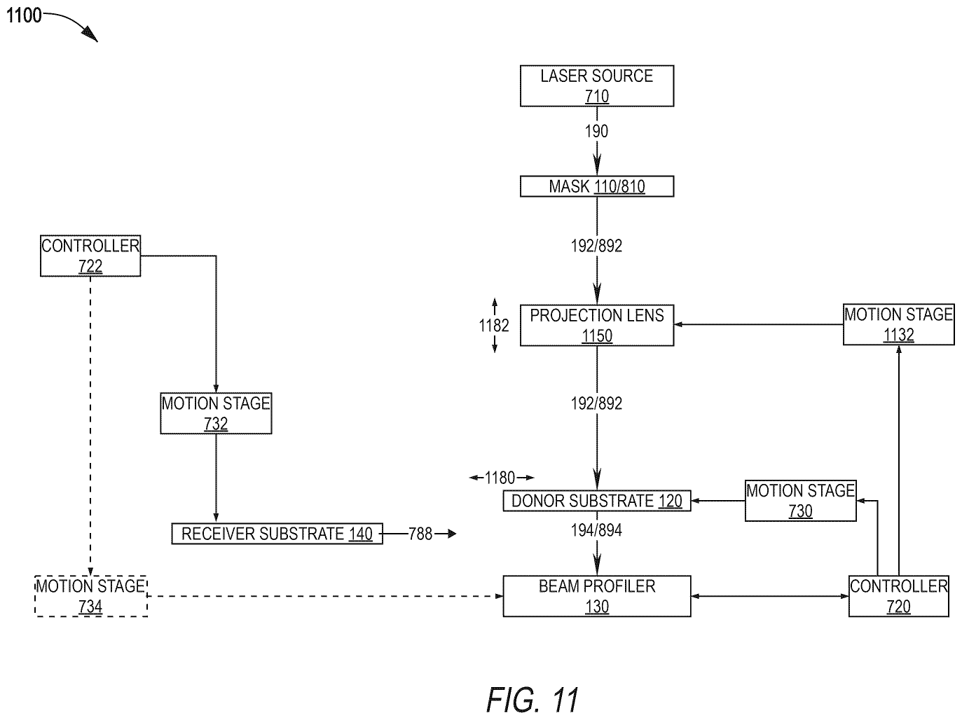

FIG. 11 illustrates one laser transfer apparatus 1100 configured to project an image of a mask onto the donor substrate. In one use scenario, apparatus 1100 performs transfer process 100. In another use scenario, apparatus 1100 performs alignment method 800 followed by a mass-transfer equivalent of LIFT method 104. Apparatus 1100 is similar to apparatus 700 except for (a) mask 110 being replaced by mask 810 in embodiments configured for mass-transfer, (b) including a projection lens 1150 between mask 110/810 and donor substrate 120, and (c) including a motion stage 1132 coupled to projection lens 1150. In addition, in apparatus 1100, it may be advantageous to couple motion stage 730 to donor substrate 120 instead of mask 110/810.

Projection lens 1150 projects an image of mask 110/810 onto donor substrate 120. In one embodiment, projection lens 1150 is configured to demagnify the image of mask 110/810 on donor substrate. Advantageously, demagnification allows for manufacturing features of mask 110/810, e.g., aperture(s) 116, on a relatively large size scale, as compared to the size of devices 122 on donor substrate 120 and the distances therebetween.

Controller 720 commands motion stage 1132 to adjust the longitudinal position of projection lens 1150 along the propagation path of masked beam 192/892, as indicated by arrow 1182, to image mask 110/810 onto donor substrate 120 with the desired (de)magnification. Motion stage 1132 is controlled by controller 720. Optionally, apparatus 1100 includes an additional motion stage, not depicted in FIG. 11, that translates mask 110/810 longitudinally to maintain a focused image of mask 110/810 on donor substrate 120 when motion stage 1132 adjusts the (de)magnification. Alternatively, motion stages 730 and 732 may be configured to translated donor substrate 120 and receiver substrate 140 longitudinally to maintain focus. Motion stage 1132 may also be capable of translating projection lens 1150 laterally to shift the image of mask 110/810 on donor substrate 120. However, it may be more practical to translate donor substrate 120 rather than projection lens 1150, as indicated by arrow 1180. Motion stage 730 may perform both translation and rotation of donor substrate 120 to correct alignment errors of the types depicted in FIGS. 9 and 10.

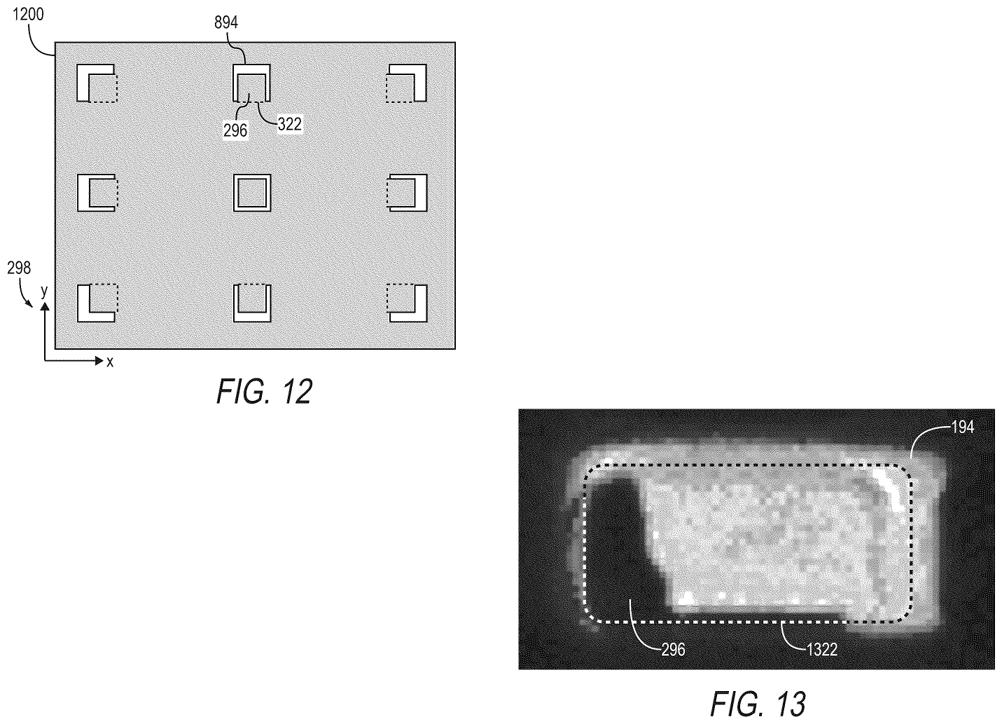

FIG. 12 is an example image 1200 captured by beam profiler 130 in apparatus 1100 during alignment method 800, in a situation where there is a (de)magnification error between mask 810 and donor substrate 120. It is evident that the image of mask 810 on donor substrate 120 is too large to match the locations of devices 122. In apparatus 1100, controller 720 may receive image 1200 from beam profiler 130 and command motion stage 1132 to adjust the longitudinal position of projection lens 1150 accordingly.

The functionality provided by beam profiler 130 may be used for other purposes than mask-to-donor alignment. For example, images captured by beam profiler 130 may be used to evaluate donor substrate 120 for defective or missing devices 122.

FIG. 13 is an example image captured by beam profiler 130 indicating a defective device 122. In this example, shadow 296 of device 122 is expected to have an outline 1322. However, as evident from transmitted beam fraction 194, a large portion of the area expected to be occupied by device 122 is transmissive, indicating that this portion of device 122 is defective or missing.

Transfer process 100, and mass-transfer equivalents thereof incorporating alignment method 800, may include evaluating imagery obtained by beam profiler 130 for defective or missing device(s) 122. Such evaluation may take place before commencing LIFT method 104 (or its mass-transfer equivalent), and the transfer process may be stopped if one or more to-be-transferred devices 122 are defective or missing. Alternatively, for example if only one out of many to-be-transferred devices 122 is defective or missing, the LIFT method may proceed and the issue resolved in a subsequent repair process.

Beam profiler 130 may also be used to check if LIFT method 104 successfully released to-be-transferred device 122 from donor substrate 120. Specifically, beam profiler 130 may be positioned as in alignment method 102 and obtain imagery of masked beam 192 transmitted to beam profiler 130. If this imagery indicates a remaining shadow of an intended-to-be-transferred device 122, LIFT method 104 was not successful.

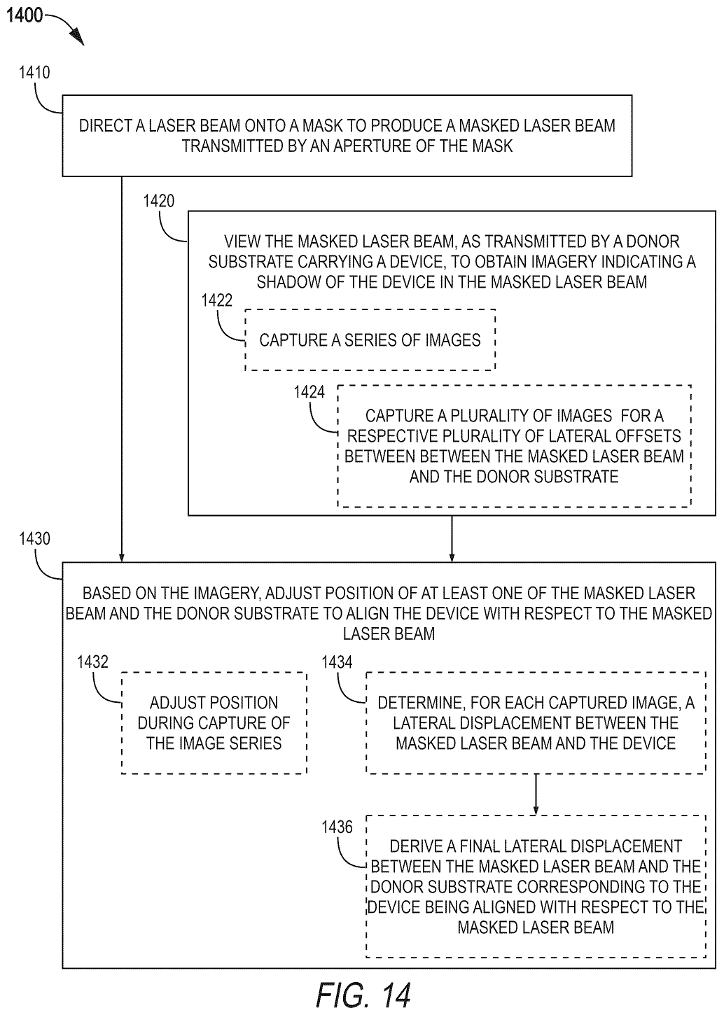

FIG. 14 is a flowchart for one mask-to-donor alignment method 1400 to aid LIFT. Each of apparatus 700 and 1100 may perform alignment method 1400. Alignment method 1400 includes an irradiation step 1410 and a viewing step 1420 performed in parallel, as well as an adjustment step 1430 that is based on imagery obtained in viewing step 1420.

Irradiation step 1410 directs a laser beam onto a mask to produce a masked laser beam transmitted by an aperture of the mask, for example as discussed for laser beam 190, mask 110, and masked beam 192 in reference to FIG. 1. Viewing step 1420 views the masked laser beam, as transmitted by a donor substrate carrying a device, to obtain imagery indicating a shadow of the device in the masked laser beam, for example as discussed for donor substrate 120, beam profiler 130, to-be-transferred device 122, and transmitted beam fraction 194 in reference to FIG. 1. Based on the imagery obtained in viewing step 1420, adjustment step 1430 adjusts the position of at least one of the masked laser beam and the donor substrate to align the device with respect to the masked laser beam, for example as discussed for masked beam 192, donor substrate 120, and to-be-transferred device 122 in reference to FIG. 1.

In one embodiment, viewing step 1420 includes a step 1422 of capturing a series of images, and adjustment step 1430 includes a step 1432 of adjusting the position of at least one of the masked laser beam and the donor substrate during the capture of the image series in step 1422. This allows for monitoring the progress of adjustment step 1430. In one example of this embodiment, viewing step 1420 and adjustment step 1430 are performed iteratively.

In certain embodiments, such as when operating without overshoot, viewing step 1420 includes a step 1424 of capturing a plurality of images for a respective plurality of lateral offsets between the masked laser beam and the donor substrate. In these embodiments, adjustment step 1430 includes (a) a step 1434 of determining, for each image captured in step 1424, a lateral offset between the masked beam and the device and (b) a step 1436 of deriving from the lateral offset determined in step 1434, a final lateral offset corresponding to the device being aligned with respect to the masked laser beam. One such embodiment is discussed above in reference to FIG. 6. Within the context of FIG. 6, the final lateral offset is the location of mask 110 that corresponds to masked beam 192 and device 122 being aligned relative to each other.

In each of apparatuses 700 and 1100, alignment method 1400 may be encoded in controllers 720 and 722 as machine-readable instructions that, when executed by a processor, cause apparatus 700/1100 to perform alignment method 1400.

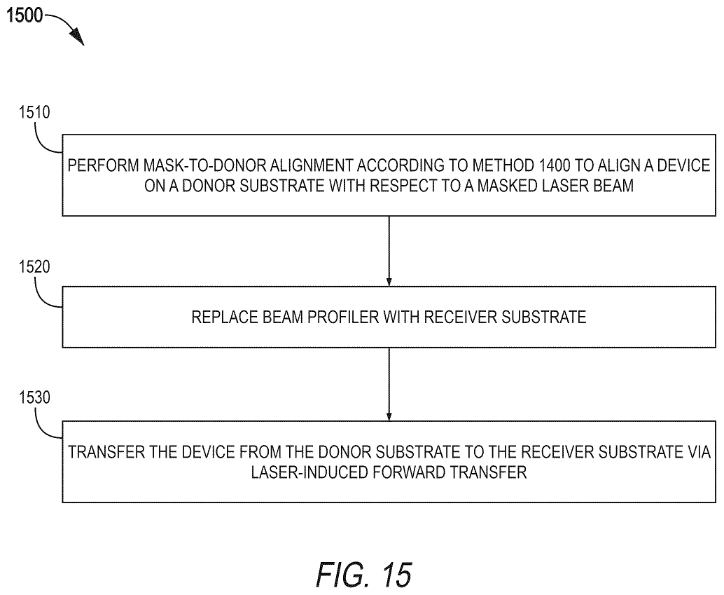

FIG. 15 is a flowchart for one laser transfer method 1500 that utilizes alignment method 1400. Laser transfer method 1500 first performs alignment method 1400 in a step 1510 to align a device on a donor substrate with respect to a masked laser beam. Next, in a step 1520, laser transfer method 1500 replaces a beam profiler, used for image capture in alignment method 1400, with a receiver substrate (e.g., receiver substrate 140 discussed above in reference to FIG. 1). Then, in a step 1530, laser transfer method 1500 transfers the device from the donor substrate to the receiver substrate via LIFT, for example as discussed above in reference to FIG. 1 and LIFT method 104.

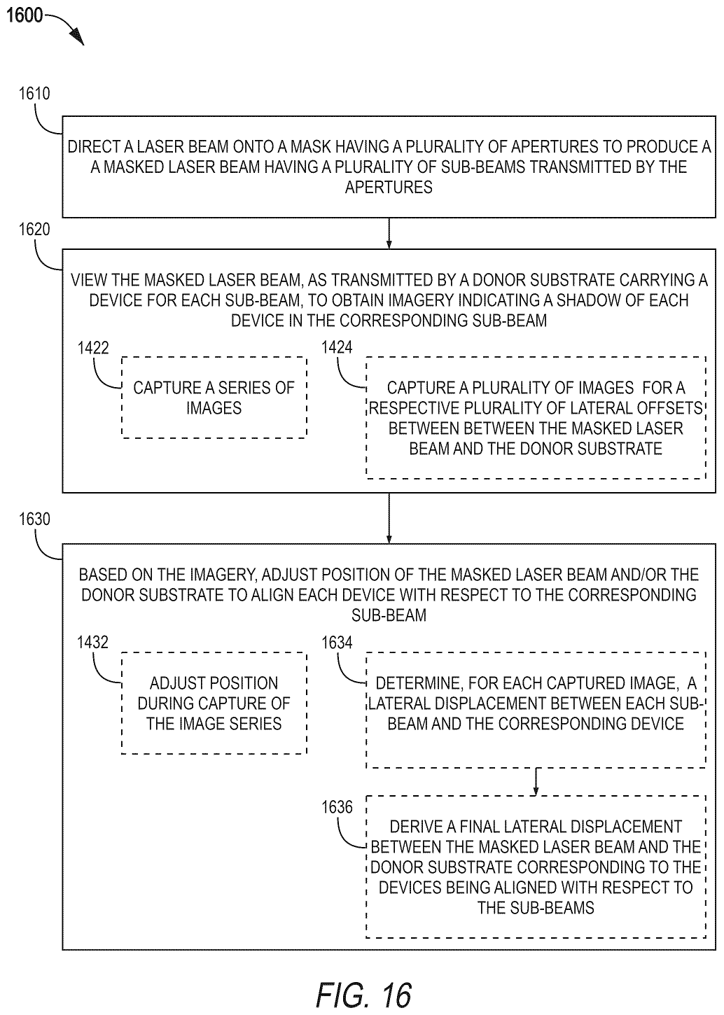

FIG. 16 is a flowchart for one mask-to-donor alignment method 1600 to aid mass-transfer of a plurality of devices via LIFT. Alignment method 1600 is an extension of alignment method 1400 from a single device to a plurality of devices. Alignment method 1600 may be performed by either one of apparatuses 700 and 1100. Alignment method 1600 includes an irradiation step 1610, a viewing step 1620, and an adjustment step 1630. Each of these steps is a respective extension of irradiation step 1410, a viewing step 1420, and an adjustment step 1430 to a plurality of devices and a respective plurality of sub-beams of a masked laser beam.

Irradiation step 1610 directs a laser beam onto a mask, having a plurality of apertures, to produce a masked laser beam having a plurality of sub-beams each transmitted by a respective aperture of the mask, for example as discussed for laser beam 190, mask 810, masked beam 892, and sub-beams 893 in reference to FIG. 8. Viewing step 1620 views the masked laser beam, as transmitted by a donor substrate carrying a device for each sub-beam, to obtain imagery indicating a shadow of each device in the corresponding sub-beam, for example as discussed for donor substrate 120, beam profiler 130, to-be-transferred devices 122, and transmitted beam fractions 894 in reference to FIG. 8. Based on the imagery obtained in viewing step 1620, adjustment step 1630 adjusts the position of the masked laser beam and/or the donor substrate to align each device with respect to the corresponding sub-beam, for example as discussed for masked beam 892, donor substrate 120, and to-be-transferred devices 122 in reference to FIG. 8.

Viewing step 1620 and adjustment step 1630 may include steps 1422 and 1432, respectively, as discussed above in reference to FIG. 14.

In certain embodiments, such as when operating without overshoot, viewing step 1620 includes step 1424 discussed above in reference to FIG. 14. In these embodiments, adjustment step 1630 includes (a) a step 1634 of determining, for each image captured in step 1424, a lateral displacement between each sub-beam and the corresponding device and (b) a step 1636 of deriving, from the lateral displacements determined in step 1634, a final lateral displacement corresponding to each device being aligned with respect to the corresponding sub-beam. For example, alignment method 800 may utilize scheme 600 extended to a plurality of devices 122, as discussed above in reference to FIG. 8.

In each of apparatuses 700 and 1100, alignment method 1600 may be encoded in controllers 720 and 722 as machine-readable instructions that, when executed by a processor, cause apparatus 700/1100 to perform alignment method 1600.

Laser transfer method 1500 is readily extendable to mass-transfer utilizing alignment method 1600 instead of alignment method 1400.

The present invention is described above in terms of a preferred embodiment and other embodiments. The invention is not limited, however, to the embodiments described and depicted herein. Rather, the invention is limited only by the claims appended hereto.

What is claimed is:

1. A mask-to-donor alignment method for laser-induced forward transfer, comprising steps of:
directing a laser beam onto a mask to produce a masked laser beam including one or more separate sub-beams, each of the one or more sub-beams being transmitted by a respective aperture of the mask;
viewing each of the one or more sub-beams, as transmitted by a donor substrate carrying one or more devices, to obtain imagery indicating in each of the one or more sub-beams a shadow of a corresponding one of the one or more devices; and
based on the imagery, adjusting position of one or both of the masked laser beam and the donor substrate, relative to each other, so as to align each of the one or more devices with respect to the corresponding sub-beam.

2. The mask-to-donor alignment method of claim 1, wherein each of the one or more devices is aligned with respect to the corresponding sub-beam when the device is centered in the corresponding sub-beam according to the imagery.

3. The mask-to-donor alignment method of claim 1, wherein each of the one or more sub-beams is characterized by a respective transverse intensity distribution that includes a flat-top portion, and each of the one or more devices is aligned with respect to the corresponding sub-beam when the device is entirely within the flat-top portion for the corresponding sub-beam.

4. The mask-to-donor alignment method of claim 1, wherein the step of adjusting includes a step of moving one of the masked laser beam and the donor substrate laterally with respect to a propagation direction of the masked laser beam, said moving including at least one of translation and rotation.

5. The mask-to-donor alignment method of claim 4, wherein the step of moving is applied to the donor substrate.

6. The mask-to-donor alignment method of claim 4, wherein the step of moving is applied to the masked laser beam and includes moving at least one of (a) the mask and (b) a projection lens arranged to project an image of the mask onto the donor substrate.

7. The mask-to-donor alignment method of claim 1, wherein the step of viewing captures a series of images and the step of adjusting is performed during capture of the series of images, so as to monitor progress of the step of adjusting.

8. The mask-to-donor alignment method of claim 1, wherein each of the one or more sub-beams has a larger footprint than the corresponding device on the donor substrate, such that at least a respective fraction of each of the one or more sub-beams passes by the corresponding device and is captured in the imagery.

9. The mask-to-donor alignment method of claim 8, wherein the step of adjusting includes increasing symmetry, around the corresponding shadow of each of the one or more devices, of the fraction of the corresponding sub-beam.

10. The mask-to-donor alignment method of claim 1, wherein, for each pair of sub-beam and corresponding device, their respective footprints on the donor substrate are of the same size.

11. The mask-to-donor alignment method of claim 1, wherein:
the one or more sub-beams include a plurality of sub-beams;
the mask has a plurality of apertures respectively transmitting the plurality of sub-beams, and the donor substrate carries a respective plurality of corresponding devices; and
the step of adjusting includes reducing an average displacement between the sub-beams and the corresponding devices.

12. The mask-to-donor alignment method of claim 11, wherein the step of adjusting includes rotating at least one of the mask and the donor substrate to reduce the average displacement.

13. The mask-to-donor alignment method of claim 11, further comprising projecting an image of the mask onto the donor substrate, and wherein the step of adjusting includes adjusting magnification of the image of the mask on the donor substrate to reduce the average displacement.

14. The mask-to-donor alignment method of claim 1, wherein:
the step of viewing is repeated for a plurality of lateral offsets between the masked laser beam and the donor substrate; and
the step of adjusting includes:
determining, from the imagery and for each pair of sub-beam and corresponding device, a lateral displacement between the sub-beam and the corresponding device for each of the lateral offsets between the masked laser beam and the donor substrate, and
deriving, from one or more lateral displacements obtained in the step of determining, a final lateral offset between the masked laser beam and the donor substrate corresponding to each of the one or more devices being aligned with respect to the corresponding sub-beam.

15. The mask-to-donor alignment method of claim 14, wherein a footprint of each of the one or more sub-beams on the donor substrate is smaller than a footprint of the corresponding device on the donor substrate but at least as large as an interface area between the corresponding device and the donor substrate.

16. The mask-to-donor alignment method of claim 1, wherein each of the one or more devices is a micro-light-emitting-diode.

17. The mask-to-donor alignment method of claim 1, wherein the step of viewing is performed by a beam profiler.

18. The mask-to-donor alignment method of claim 1, further comprising evaluating the imagery for laser-beam transmission indicative of a defective device.

19. A transfer process, comprising steps of:
performing the mask-to-donor alignment method of claim 1 to establish an alignment between the masked laser beam and the donor substrate; and
transferring each of the one or more devices from the donor substrate to a receiver substrate via laser-induced forward transfer by irradiating each respective device of the one or more devices with the corresponding sub-beam, while maintaining the alignment established by the step of performing the mask-to-donor alignment method.

20. The transfer process of claim 19, wherein the step of transferring is performed with a higher power of the laser beam than the step of directing.

21. The transfer process of claim 19, further comprising, after the step of transferring, translating one of (a) the masked laser beam and (b) the donor and receiver substrates by a predetermined amount, to aim the masked laser beam at one or more additional devices on the donor substrate so as to effect laser-induced forward transfer of each of the one or more additional devices to the receiver substrate.

22. The transfer process of claim 19, further comprising, after the step of transferring, removing the receiver substrate and re-viewing each of the one or more sub-beams as transmitted by the donor substrate, to confirm successful release of each of the one or more corresponding devices from the donor substrate in the step of transferring.
